(19) United States
(12) Patent Application Publication
(10) Pub. No.: US 2026/0018446 A1
(43) Pub. Date: Jan. 15, 2026

(54) CHAMBER DOCKING APPARATUS, SUBSTRATE TRANSPORT APPARATUS AND SUBSTRATE PROCESSING SYSTEM INCLUDING THE SAME

(71) Applicant: SAMSUNG ELECTRONICS CO., LTD., SUWON-SI (KR)

(72) Inventors: Heesu CHUNG, Suwon-si (KR); Doyeon KIM, Suwon-si (KR); Jiwoong KIM, Suwon-si (KR); Jonghyeok PARK, Suwon-si (KR); Jubok LEE, Suwon-si (KR); SeungGyo JEONG, Suwon-si (KR)

(21) Appl. No.: 19/027,715

(22) Filed: Jan. 17, 2025

(30) Foreign Application Priority Data
Jul. 10, 2024 (KR) 10-2024-0090821

(51) Int. Cl. H01L 21/677; B65G 47/90

(52) U.S. Cl. CPC H01L 21/67742; B65G 47/90

(57) ABSTRACT

A chamber docking apparatus connecting a first chamber to a second chamber includes: a first fixed body having a passage penetrating from a first end to the second end thereof through which a substrate passes, and communicating with the first chamber; a second fixed body having a passage penetrating from a first end and to a second end thereof through which the substrate passes, and communicating with the second chamber; a length-adjusted body having a passage through which the substrate passes, and configured to adjust in length; and a length-adjusting driver for adjusting the length of the length-adjusted body, and wherein a first end of the length-adjusted body is connected to the second end of the first fixed body, and a second end of the length-adjusted body is detachably connected to the second end of the second fixed body, and wherein the length-adjusted body includes: a bellows portion.

### CROSS-REFERENCE TO RELATED APPLICATION

This application claims priority under 35 U.S.C. § 119 to Korean Patent Application No. 10-2024-0090821, filed on Jul. 10, 2024 in the Korean Intellectual Property Office, the disclosure of which is incorporated by reference herein in its entirety.

### TECHNICAL FIELD

The present inventive concept relates to a chamber docking apparatus, and a substrate transfer apparatus and substrate processing system including the same, and more particularly, to a chamber docking apparatus connecting chambers for processing substrates in a vacuum state so that the substrates can be transported, and a substrate transfer apparatus and substrate processing system including the same.

### DISCUSSION OF THE RELATED ART

Some of the processes for processing substrates such as semiconductors or display panels require that the pressure inside the chamber be in a vacuum state. In addition, a passage connecting chambers, which require a vacuum state, also requires an internal vacuum state. To stably provide the internal vacuum state of such chambers and passages, each process and substrate transport are performed while the passages and the chambers are fixed to each other.

Therefore, vibrations of a vacuum pump or other equipment, which maintain and/or provide the vacuum state within each chamber and passage, may be transmitted to other chambers. These vibrations that may be transmitted from other devices may cause errors and/or damage to the substrate processing process.

For example, these vibrations may have an impact on the image quality of a chamber where imaging of a substrate is performed by using a scanning electron microscope (SEM).

### SUMMARY

According to an example embodiment of the present inventive concept, a chamber docking apparatus connecting a first chamber and a second chamber to each other includes: a first fixed body having a passage penetrating from a first end to the second end thereof through which a substrate passes, and communicating with an entrance of the first chamber; a second fixed body having a passage penetrating from a first end and to a second end thereof through which the substrate passes, and communicating with an entrance of the second chamber; a length-adjusted body having a passage through which the substrate passes inside, and configured to adjust in length; and a length-adjusting driver for adjusting the length of the length-adjusted body, and wherein a first end of the length-adjusted body is connected to the second end of the first fixed body, and a second end of the length-adjusted body is detachably connected to the second end of the second fixed body, and wherein the length-adjusted body includes: a bellows portion including a side wall that includes a bellows structure.

According to an example embodiment of the present inventive concept, a substrate transfer apparatus includes: a chamber docking apparatus connecting substrate processing devices to each other; and a substrate transfer portion transferring the substrate between the substrate processing devices through the chamber docking apparatus, and wherein the substrate transfer portion includes: a first chamber having a space therein where the substrate is transferred and communicating with one of the substrate processing devices; and a transfer robot provided in the first chamber and transferring the substrate between the substrate processing devices through the first chamber and the chamber docking apparatus, and wherein the other of the substrate processing devices includes: a second chamber having a space therein where the substrate is processed, and wherein the chamber docking apparatus includes: a first fixed body having a passage penetrating from a first end to a second end thereof through which the substrate passes, and communicating with an entrance of one of the first chamber or the second chamber; a second fixed body having a passage penetrating from a first end to a second end thereof through which the substrate passes, and communicating with an entrance of the other of the first chamber or the second chamber; a length-adjusted body having a passage through which the substrate passes inside, and configured to adjust in length; and a length-adjusting driver for adjusting the length of the length-adjusted body, and wherein a first end of the length-adjusted body is connected to the second end of the first fixed body, and the second end of the length-adjusted body is detachably connected to the second end of the second fixed body, and wherein the length-adjusted body includes: a bellows portion including a side wall that includes a bellows structure.

According to an example embodiment of the present inventive concept, a substrate processing system includes: a first substrate processing device processing a substrate; a second substrate processing device processing the substrate before or after the first substrate processing device; and a substrate transfer apparatus transferring the substrate between the first substrate processing device and the second substrate processing device, and wherein the substrate transfer apparatus includes: a chamber docking apparatus connecting the first substrate processing device and the second substrate processing device to each other; and a substrate transfer portion transferring the substrate between the first substrate processing device and the second substrate processing device through the chamber docking apparatus, wherein the substrate transfer portion includes: a first chamber having a space therein where the substrate is transferred and communicating with the first substrate processing device, and a transfer robot provided in the first chamber and transferring the substrate between the first substrate processing device and the second substrate processing device through the first chamber and the chamber docking apparatus, and wherein the second substrate processing device includes: a second chamber having a space therein where the substrate is processed, and wherein the chamber docking apparatus includes: a first fixed body having a passage penetrating from a first end to a second end thereof through which the substrate passes, and communicating with an entrance of one of the first chamber and the second chamber; a second fixed body having a passage penetrating from a first end to a second end thereof through which the substrate passes, and communicating with an entrance of the other of the first chamber or the second chamber; a length-adjusted body having a passage through which the substrate passes inside, and configured to adjust in length; and a length-adjusting driver for adjusting the length of the length-adjusted body, and wherein a first end of the length-adjusted body is connected to the second end of the first fixed body, and the second end of the length-adjusted body is detachably connected to the second end of the second fixed body, and wherein the length-adjusted body includes: a bellows portion including a side wall that includes a bellows structure.

### BRIEF DESCRIPTION OF DRAWINGS

The above and other aspects and features of the present inventive concept will be more clearly understood from the following detailed description, taken in conjunction with the accompanying drawings.

FIG. 1 is a plan view schematically illustrating a substrate processing system according to an example embodiment of the present inventive concept.

FIG. 2 is a perspective view illustrating an example in which the second fixed body and the length-adjusted body of the chamber docking apparatus illustrated in FIG. 1 are separated.

FIG. 3 is a view of the chamber docking apparatus of FIG. 2 as viewed in a y direction.

FIG. 4 is a view of the chamber docking apparatus of FIG. 2 as viewed from above.

FIG. 5 is a view of an example in which the second fixed body and the length-adjusted body of the chamber docking apparatus illustrated in FIG. 1 are connected, as viewed from above.

FIG. 6 is a view of the support portion of FIG. 5 as viewed from the position of the second fixed body.

FIG. 7 is a view of the second fixed body of FIG. 5 as viewed from the position of the support portion.

FIG. 8 is a view illustrating an example in which the clamp illustrated in FIG. 5 fixes the second fixed body and the length-adjusted body to each other.

FIG. 9 is a view illustrating an example in which the clamp illustrated in FIG. 5 releases the fixation between the second fixed body and the length-adjusted body.

FIGS. 10, 11, 12, 13, 14, 15, 16, and 17 are views illustrating sequentially the process in which a substrate is transferred from the first chamber to the second chamber by the chamber docking apparatus of FIG. 2.

FIG. 18 is a perspective view illustrating a chamber docking apparatus according to an example embodiment of the present inventive concept.

FIG. 19 is a view of the chamber docking apparatus of FIG. 18 as viewed in the y direction.

FIG. 20 is a drawing of the chamber docking apparatus of FIG. 18 as viewed from above.

FIG. 21 is a perspective view illustrating the first fixed body and the length-adjusted body of FIG. 18 so that the surface facing the second fixed body of the support portion is visible.

FIG. 22 is a perspective view illustrating the second fixed body of FIG. 18 so that the surface thereof facing the length-adjusted body is visible.

FIG. 23 is a cross-sectional view illustrating the inside of the clamp body with the clamp protrusion inserted into the protrusion insertion hole.

FIG. 24 is a cross-sectional view illustrating the inside of the clamp body with the clamp protrusion separated from the protrusion insertion hole.

### DETAILED DESCRIPTION OF THE EMBODIMENTS

Hereinafter, embodiments of the present inventive concept will be described more fully hereinafter with reference to the accompanying drawings. In the figures and specification, like reference numerals may denote like elements or features, and thus repetitive descriptions may be omitted.

According to example embodiments of the present inventive concept, a substrate processing system may be used to perform a process on a substrate such as a semiconductor wafer or a flat display panel.

Example embodiments of the present inventive concept may relate to a chamber docking apparatus, substrate transfer apparatus, and substrate processing system designed to increase the precision and efficiency of substrate processing, particularly in vacuum environments. Example embodiments of the present inventive concept focus on the challenge of isolating vibrations from connected devices, which can adversely affect sensitive processes such as imaging that is performed by a scanning electron microscope (SEM). The chamber docking apparatus, the substrate transfer apparatus, and the substrate processing system, according to example embodiments of the present inventive concept, may minimize these disturbances, thereby ensuring stable substrate transport and processing.

In example embodiments of the present inventive concept, the chamber docking apparatus connects two chambers—a first chamber for transferring substrates and a second chamber for processing substrates—via a length-adjustable passage. This passage is made up of a first fixed body, a second fixed body, and a length-adjusted body that includes a bellows structure for flexibility. A length-adjusting driver adjusts the passage length to connect or disconnect the chambers as needed, thereby mitigating vibration transmission during sensitive processes. The apparatus also includes a guiding portion and a clamp to ensure precise alignment and secure attachment of the connected components.

According to example embodiments of the present inventive concept, a substrate transfer apparatus employs the chamber docking apparatus to facilitate the movement of substrates between chambers. This system includes a transfer robot housed in a first chamber, which moves substrates between processing devices while maintaining vacuum conditions. A pressure controller independently manages the internal pressure of each chamber and the connecting passage, allowing the system to toggle between vacuum and atmospheric states.

Overall, the substrate processing system, which may include the chamber docking apparatus and transfer apparatus, may enable vibration-isolated substrate transfer and processing.

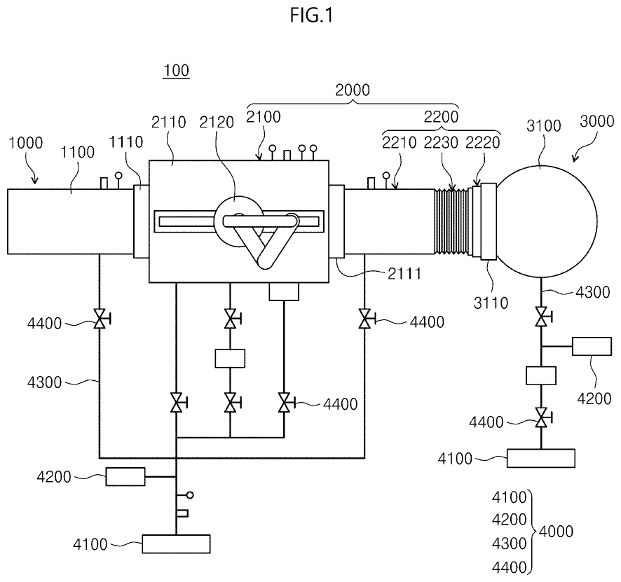

FIG. 1 is a plan view schematically illustrating a substrate processing system 100 according to an example embodiment of the present inventive concept.

Referring to FIG. 1, the substrate processing system 100 may include a first substrate processing device 1000, a substrate transfer apparatus 2000, and a second substrate processing device 3000. The first substrate processing device 1000, the substrate transfer apparatus 2000, and the second substrate processing device 3000 may be sequentially arranged in a row in one direction. However, the arrangement structure of the first substrate processing device 1000, the substrate transfer apparatus 2000 and the second substrate processing device 3000 is not limited thereto.

Hereinafter, in the present embodiment, the direction in which the first substrate processing device 1000, the substrate transfer apparatus 2000 and the second substrate processing device 3000 are arranged is referred to as the x-direction 11. The direction perpendicular to the x-direction 11 when viewed from above is referred to as the y-direction 12, and the direction perpendicular to the x-direction 11 and the y-direction 12 is referred to as the z-direction 13.

The first substrate processing device 1000 processes the substrate 10. The first substrate processing device 1000 may be provided as a device capable of processing the substrate 10 in a vacuum state. For example, the first substrate processing device 1000 may be provided as a load lock chamber. However, the type of the first substrate processing device 1000 is not limited thereto. The first substrate processing device 1000 may include a chamber 1100.

The chamber 1100 has a space in which a substrate 10 is temporarily accommodated therein. An entrance is formed on one side of the chamber 1100 so that the substrate 10 may move between the chamber 1100 and the substrate transfer potion 2100. A door 1110 for opening and closing the entrance may be provided at the entrance of the chamber 1100. The door 1110 may seal the interior of the chamber 1100 when closed.

The substrate transfer apparatus 2000 transfers a substrate between substrate processing devices that process a substrate 10. According to an example embodiment of the present inventive concept, the substrate transfer apparatus 2000 transfers a substrate 10 between a first substrate processing device 1000 and a second substrate processing device 3000. The substrate transfer apparatus 2000 may include a substrate transfer potion 2100 and a chamber docking apparatus 2200.

The substrate transfer potion 2100 transfers a substrate 10 between substrate processing devices that process a substrate 10 through the chamber docking apparatus 2200. According to an example embodiment of the present inventive concept, the substrate transfer potion 2100 transfers the substrate 10 between the first substrate processing device 1000 and the second substrate processing device 3000 through the chamber docking apparatus 2200. The substrate transfer potion 2100 may include a first chamber 2110 and a transfer robot 2120.

The first chamber 2110 has a space inside where the substrate 10 is transferred. The first chamber 2110 is connected to one of the substrate processing devices that are substrate transfer targets of the substrate transfer apparatus 2000 so that the substrate 10 may be transferred. According to an example embodiment of the present inventive concept, the first chamber 2110 is connected to the first substrate processing device 1000 so that the substrate 10 may be transferred between the first substrate processing device 1000 and the first chamber 2110. An entrance is formed on one side surface of the first chamber 2110 so that the substrate 10 may move between the first chamber 2110 and the chamber docking apparatus 2200. A first door 2111 for opening and closing the entrance of the first chamber 2110 may be provided at the entrance of the first chamber 2110. The first door 2111 may seal the interior of the first chamber 2110 when the first door 2111 is closed.

The transfer robot 2120 transfers the substrate 10 between the substrate processing devices that are the substrate transfer targets of the substrate transfer apparatus 2000 through the first chamber 2110 and the chamber docking apparatus 2200. According to an example embodiment of the present inventive concept, the transfer robot 2120 is provided within the first chamber 2110. The transfer robot 2120 transfers the substrate 10 between the first substrate processing device 1000 and the second substrate processing device 3000 through the first chamber 2110 and the chamber docking apparatus 2200. The transfer robot 2120 may be provided in various configurations and structures that may transfer the substrate 10 between the substrate processing devices that are the substrate transfer targets of the substrate transfer apparatus 2000 through the first chamber 2110 and the chamber docking apparatus 2200.

The second substrate processing device 3000 may be a device that performs a process before or after the first substrate processing device 1000 on the substrate 10. According to an example embodiment of the present inventive concept, the second substrate processing device 3000 may perform a process after the first substrate processing device 1000 on the substrate 10. For example, the second substrate processing device 3000 may perform a process of capturing an image of a substrate 10 by using a scanning electron microscope (SEM). The second substrate processing device 3000 may include a second chamber 3100 and a scanning electron microscope. However, the type of the second substrate processing device 3000 is not limited thereto.

The second chamber 3100 has an interior space in which a substrate 10 is processed. An entrance is formed on one side surface of the second chamber 3100 so that the substrate 10 may move between the second chamber 3100 and the chamber docking apparatus 2200. A second door 3110 for opening and closing the entrance of the second chamber 3100 may be provided at the entrance of the second chamber 3100. The second door 3110 may seal the inside of the second chamber 3100 when the second door 3110 closed.

The scanning electron microscope directs an electron beam onto the surface of a substrate 10, which is accommodated in the second chamber 3100. While the internal pressure of the second chamber 3100 remains at vacuum pressure, the microscope captures an image of the surface of the substrate 10.

The chamber docking apparatus 2200 connects the substrate processing devices so that the substrate 10 may be transferred between the substrate processing devices that process the substrate 10. According to an example embodiment of the present inventive concept, the chamber docking apparatus 2200 connects the first substrate processing device 1000 and the second substrate processing device 3000 so that the substrate 10 may be transferred between them.

The pressure control portion (e.g., a pressure controller) 4000 independently may control the internal pressures of the chamber 1100, the first chamber 2110, the chamber docking apparatus 2200 and the second chamber 3100. According to an example embodiment of the present inventive concept, the chamber pressure control portion 4000 may control the internal pressure of the chamber 1100, the first chamber 2110, the chamber docking apparatus 2200 and the second chamber 3100 in a range from vacuum pressure to atmospheric pressure. The chamber pressure control portion 4000 may include a vacuum pump 4100, a pressurizing gas supply portion 4200, a gas movement line 4300, and a valve 4400.

The vacuum pump 4100 provides a negative pressure for discharging gas within the chamber 1100, the first chamber 2110, the chamber docking apparatus 2200 and the second chamber 3100.

The pressurizing gas supply portion 4200 provides an inert gas to increase the pressure above the atmospheric pressure inside the chamber 1100, the first chamber 2110, the chamber docking apparatus 2200 and the second chamber 3100. For example, the inert gas may be provided as nitrogen (N2) gas. However, the type of the inert gas is not limited thereto.

The gas movement line 4300 is provided as a path through which gas is discharged from the chamber 1100, the first chamber 2110, the chamber docking apparatus 2200 and the second chamber 3100 by the vacuum pump 4100, and gas is supplied to the chamber 1100, the first chamber 2110, the chamber docking apparatus 2200 and the second chamber 3100 by the pressurizing gas supply portion 4200.

The valve 4400 controls the gas supply and gas discharge of the chamber 1100, the first chamber 2110, the chamber docking apparatus 2200, and the second chamber 3100 by opening and closing the gas movement line 4300.

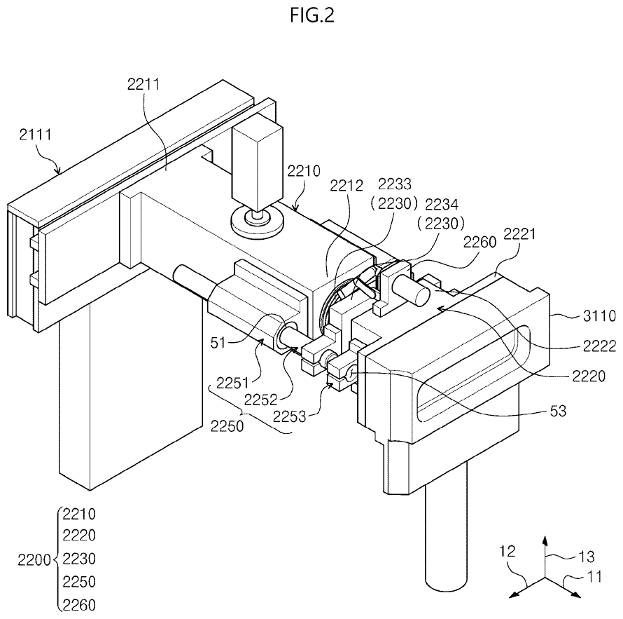

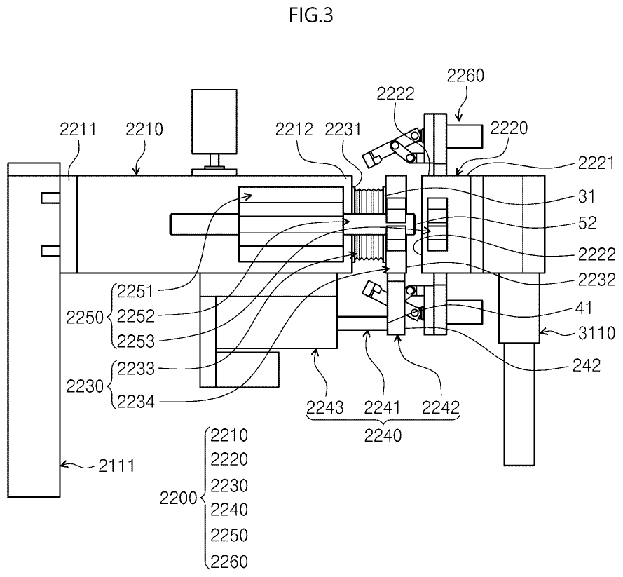

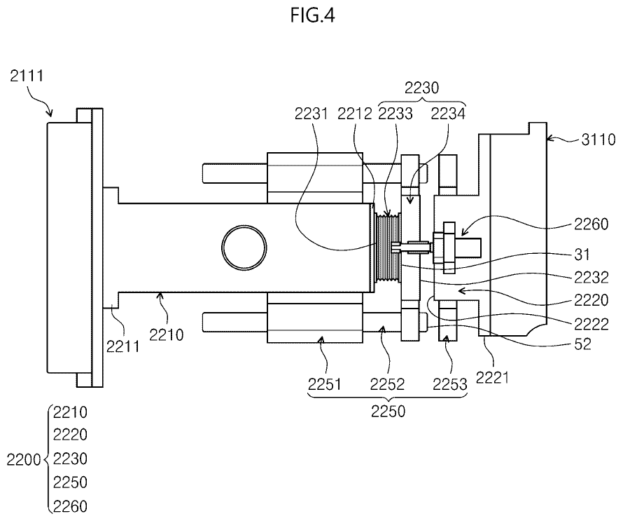

FIG. 2 is a perspective view illustrating an example in which the second fixed body 2220 and the length-adjusted body 2230 of the chamber docking apparatus 2200 illustrated in FIG. 1 are separated. FIG. 3 is a view of the chamber docking apparatus 2200 of FIG. 2 as viewed in the y direction 12. FIG. 4 is a view of the chamber docking apparatus 2200 of FIG. 2 as viewed from above.

Referring to FIGS. 2 to 4, the chamber docking apparatus 2200 may include a first fixed body 2210, a second fixed body 2220, a length-adjusted body 2230, a length-adjusting driving portion (e.g., a length-adjusting driver) 2240, a guide portion 2250 and a clamp 2260.

The first fixed body 2210 may have a passage penetrating from one end (e.g., a first end) 2211 to the other end (e.g., a second end) 2212 thereof so that the passage is formed in the first fixed body 2210 through which a substrate 10 passes therein. The first fixed body 2210 may be connected to the entrance of one of the first chamber 2110 and the second chamber 3100. According to an example embodiment of the present inventive concept, the first fixed body 2210 may be connected to the entrance of the first chamber 2110.

The second fixed body 2220 may have a passage from one end (e.g., a first end) 2221 to the other end (e.g., a second end) 2222 so that a passage is formed inside the second fixed body 2220 through which a substrate 10 passes. The second fixed body 2220 may be connected to the other entrance of the first chamber 2110 and the second chamber 3100. According to an example embodiment of the present inventive concept, the second fixed body 2220 may be connected to the entrance of the second chamber 3100.

The length-adjusted body 2230 may have a passage therein, through which a substrate 10 passes. One end (e.g., a first end) 2231 of the length-adjusted body 2230 may be communicated to the other end 2212 of the first fixed body 2210. The other end (e.g., a second end) 2232 of the length-adjusted body 2230 may be provided to be detachably communicated to the other end 2222 of the second fixed body 2220. The length-adjusted body 2230 may be provided so that the length thereof may be adjusted. According to an example embodiment of the present inventive concept, the length-adjusted body 2230 may include a bellows portion 2233 and a support portion 2234.

The bellows portion 2233 may include a sidewall, and at least a part of the side wall has a bellows structure according to the longitudinal direction of the bellows portion 2233. The bellows structure may be provided with a material that may withstand the pressure difference between the vacuum pressure inside the bellows portion 2233 and the atmospheric pressure outside the bellows portion 2233. According to an example embodiment of the present inventive concept, the bellows structure may be provided with a SUS material. However, the material of the bellows structure is not limited thereto.

The support portion 2234 may extend from one end (e.g., a first end) 31 of the bellows portion 2233 toward the second fixed body 2220. When viewed along the x-direction 11, the outer circumference surface of the support portion 2234 protrudes outwardly beyond the outer circumference surface of the bellows portion 2233. The support portion 2234 may be provided as an open ring structure (e.g., an annular structure) in which an area corresponding to the open area of one end 31 of the bellows portion 2233 allows the substrate 10 to enter and exit between the inside and outside of the bellows portion 2233.

The length-adjusting driving portion 2240 may adjust the length of the length-adjusted body 2230. According to an example embodiment of the present inventive concept, the length-adjusting driving portion 2240 may include a length-adjusting shaft 2241, a shaft connection portion 2242, and an actuator 2243.

One end (e.g., a first end) 41 of the length-adjusting shaft 2241 is connected to the other end 2232 of the length-adjusted body 2230. The length-adjusting shaft 2241 may extend parallel to the longitudinal direction of the length-adjusted body 2230 toward the first fixed body 2210. According to an example embodiment of the present inventive concept, the length-adjusting shaft 2241 may be provided as a cylindrical structure whose longitudinal direction is parallel to the x-direction 11.

The shaft connection portion 2242 may extend outward from the side surface of the other end 2232 of the length-adjusted body 2230. The end 242 of the shaft connection portion 2242 is connected to the one end 41 of the length-adjusting shaft 2241. For example, the end 242 of the shaft connection portion 2242 may face in a direction away from the length-adjusted body 2230.

The actuator 2243 may be connected to the first fixed body 2210. The actuator 2243 moves the length-adjusting shaft 2241 along the longitudinal direction of the length-adjusting shaft 2241. According to an example embodiment of the present inventive concept, the actuator 2243 may move the length-adjusting shaft 2241 along the x-direction 11. The actuator 2243 may be installed on one side surface of the first fixed body 2210. According to an example embodiment of the present inventive concept, the actuator 2243 may be installed on the lower surface of the first fixed body 2210. For example, the actuator 2243 may be provided as a linear motor.

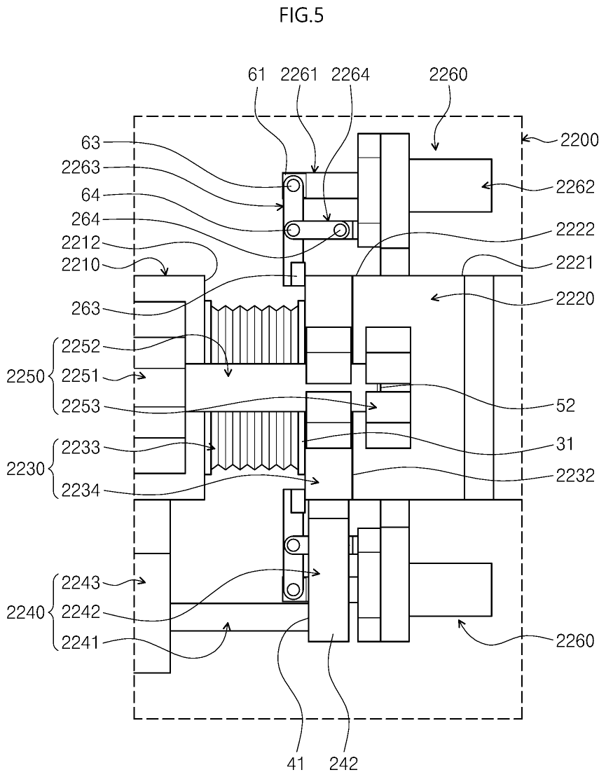

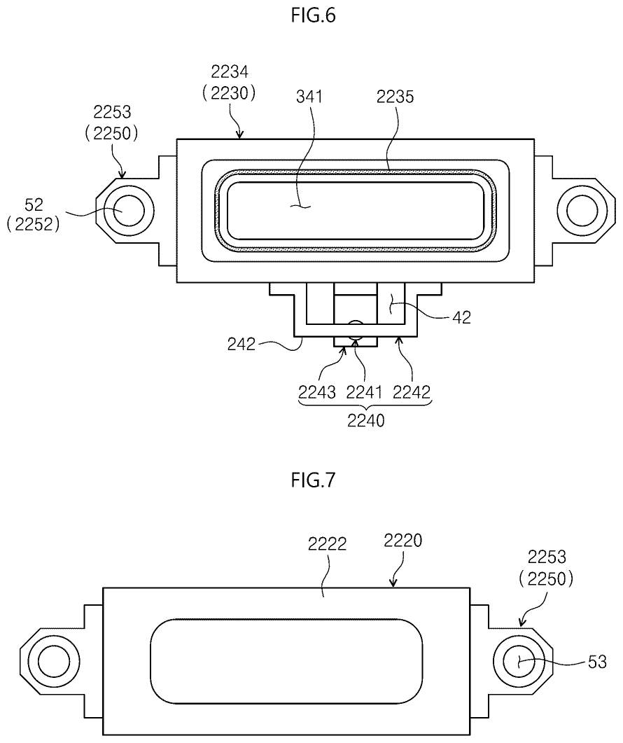

FIG. 5 is a view of an example in which the second fixed body 2220 and the length-adjusted body 2230 of the chamber docking apparatus 2200 illustrated in FIG. 1 are connected to each other, as viewed from above. FIG. 6 is a view of the support portion 2234 of FIG. S as viewed from the position of the second fixed body 2220. FIG. 7 is a view of the second fixed body 2220 of FIG. 5 as viewed from the position of the support portion 2234.

Referring to FIGS. 5 to 7, the guide portion 2250 may guide the length adjustment direction of the length-adjusted body 2230. According to an example embodiment of the present inventive concept, the guide portions 2250 may be provided on each side surface of the chamber docking apparatus 2200. For example, the guide portions 2250 may be disposed on side surfaces of the chamber docking apparatus 2200 that are opposite to each other. The guide portions 2250 may include a guide body 2251, a guide shaft 2252 and an insertion body 2253.

The guide body 2251 is installed on one side surface of the first fixed body 2210. According to an example embodiment of the present inventive concept, one of the guide bodies 2251 may be installed on a first side surface of the first fixed body 2210. The other of the guide bodies 2251 may be installed on a second side surface that is opposite to the first side surface of the first fixed body 2210. A guide hole 51 may be formed in each of the guide bodies 2251 along the length adjustment direction, and a guide shaft 2252 may move through a corresponding guide body 2251 via the guide hole 51. According to an example embodiment of the present inventive concept, each of the guide holes 51 may penetrate the guide bodies 2251 along the x direction.

The guide shafts 2252 may be provided in a number corresponding to the number of the guide bodies 2251. Each of the guide shafts 2252 may be inserted into and engaged with the guide holes 51 so as to be movable along the length adjustment direction. Each of the guide shafts 2252 may have one end 52 connected to the other end 2232 of the length-adjusted body 2230. The one end 52 of the guide shafts 2252 may protrude in a direction parallel to the length adjustment direction toward the second fixed body 2220 more than the other end 2232 of the length-adjusted body 2230. For example, the one end 52 of the guide shafts 2252 may protrude beyond the other end 2232 of the length-adjusted body 2230.

The insertion bodies 2253 may be provided in numbers corresponding to the numbers of the guide bodies 2251 and the guide shafts 2252. The insertion bodies 2253 may be installed on opposite side surfaces of the second fixed body 2220, respectively. An insertion hole 53 is formed in each of the insertion bodies 2253. Each one end 52 of the guide shafts 2252 is inserted into a corresponding insertion hole 53 such that the guide shaft 2252 and the corresponding insertion hole 53 are engaged with each other.

As described above, by providing the guide bodies 2251 and the guide shafts 2252, the support portion 2234 of the length-adjusted body 2230 may be fastened to the correct position of the second fixed body 2220. In addition, since the insertion hole 53 of the insertion bodies 2253 is provided to be engaged with the guide shafts 2252, the support portion 2234 may maintain the correct position while being fastened to the second fixed body 2220.

The clamp 2260 may fix the second fixed body 2220 and the length-adjusted body 2230 to each other while the second fixed body 2220 and the length-adjusted body 2230 are in contact with each other. The clamp 2260 may release the fixation to reduce the length of the length-adjusted body 2230 and separate the second fixed body 2220 and the length-adjusted body 2230 from each other. The clamp 2260 may be provided in various configurations and structures that may fix the second fixed body 2220 and the length-adjusted body 2230 to each other, and release the fixation between the second fixed body 2220 and the length-adjusted body 2230.

According to an example embodiment of the present inventive concept, the shaft connection portion 2242 may be provided at a position that overlaps the clamp 2260 when viewed along the x-direction 11. In example embodiments of the present inventive concept, the shaft connection portion 2242 may be opened so that the clamp 2260 may pass through the area 42 that overlaps the clamp 2260 when viewed along the x-direction 11. Therefore, interference between the shaft connection portion 2242 and the clamp 2260 may be prevented.

A sealing ring 2235 may be provided in an area surrounding an open area 341 of a surface facing the second fixed body 2220 of the support portion 2234. The sealing ring 2235 may seal the space between the support portion 2234 and the second fixed body 2220.

A plurality of clamps 2260 may be provided. According to an example embodiment of the present inventive concept, each of the clamps 2260 may be installed on the upper surface and the lower surface of the second fixed body 2220.

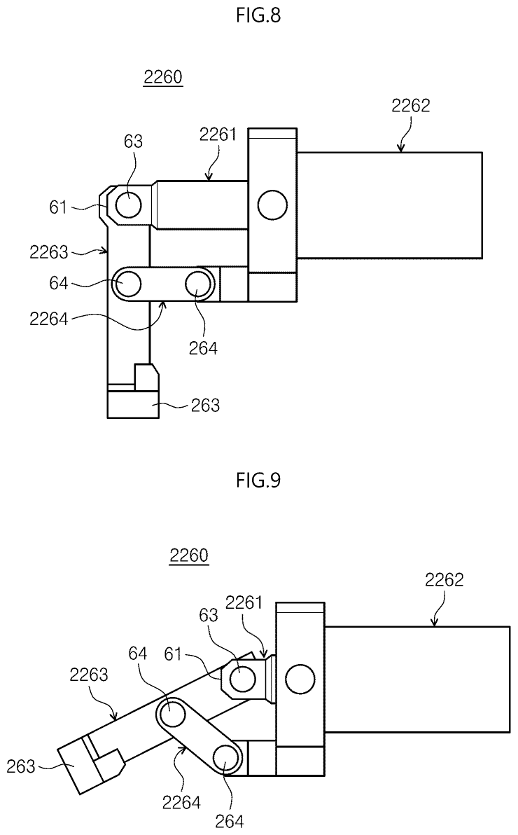

FIG. 8 is a view illustrating an example in which the clamp 2260 illustrated in FIG. 5 fixes the second fixed body 2220 and the length-adjusted body 2230 to each other. FIG. 9 is a view illustrating an example in which the clamp 2260 illustrated in FIG. 5 releases the fixation between the second fixed body 2220 and the length-adjusted body 2230.

Referring to FIGS. 5, 8, and 9, according to an example embodiment of the present inventive concept, the clamp 2260 may include a piston 2261, a piston driving portion (e.g., a piston driver) 2262, a holding frame 2263, and a guide frame 2264.

The piston 2261 may be spaced apart from the outer circumference surface of the second fixed body 2220. The piston 2261 may be provided to be reciprocally movable along the x-direction 11 with respect to the second fixed body 2220. The piston 2261 may be provided as a bar structure having a longitudinal direction parallel to the x-direction 11.

The piston driving portion 2262 may reciprocate the piston 2261 along the x-direction 11. According to an example embodiment of the present inventive concept, the piston driving portion 2262 may be provided as a pneumatic actuator.

The holding frame 2263 may be connected to the end 61, which faces the first fixed body 2210, of the piston 2261 so that one end 63 may rotate about an axis in the y-direction 12. The holding frame 2263 may be provided as a bar structure extending from the one end 63 in a length direction that is parallel to the rotational radial direction with respect to the holding frame 2263 that rotates about an axis that extends in the y-direction 12.

The guide frame 2264 is connected between one end (e.g., a first end) 63 and the other end (e.g., a second end) 263 of the holding frame 2263 so that one end (e.g., a first end) 64 may rotate about an axis that extends in the y-direction 12. The other end (e.g., a second end) 264 of the guide frame 2264 may be connected to the piston driving portion 2262 at a position that is between the piston 2261 and the second fixed body 2220 and farther from the first fixed body 2210 than the end 61 of the piston 2261 to be rotatable about an axis that extends in the y direction

Since the clamp 2260 is provided with the above-described configuration and structure, as illustrated in FIG. 8, when the second fixed body 2220 and the support portion 2234 are in contact with each other, and the piston 2261 moves toward the first fixed body 2210 to be in a first position, the other end 263 of the holding frame 2263 comes into contact with the surface of the support portion 2234 that faces the first fixed body 2210 and protrudes outwardly beyond the bellows portion 2233. Therefore, the clamp 2260 may fix the second fixed body 2220 and the support portion 2234 to each other.

In addition, as illustrated in FIG. 9, when the piston 2261 moves from the above-mentioned first position toward the second chamber 3100 and is located at a position farther from the first fixed body 2210 than the above-mentioned first position, the other end 263 of the holding frame 2263 is separated from the support portion 2234. Therefore, the clamp 2260 may release the fixation between the second fixed body 2220 and the support portion 2234.

As described above, by providing the clamp 2260, the fastening state between the second fixed body 2220 and the length-adjusted body 2230 may be maintained more firmly.

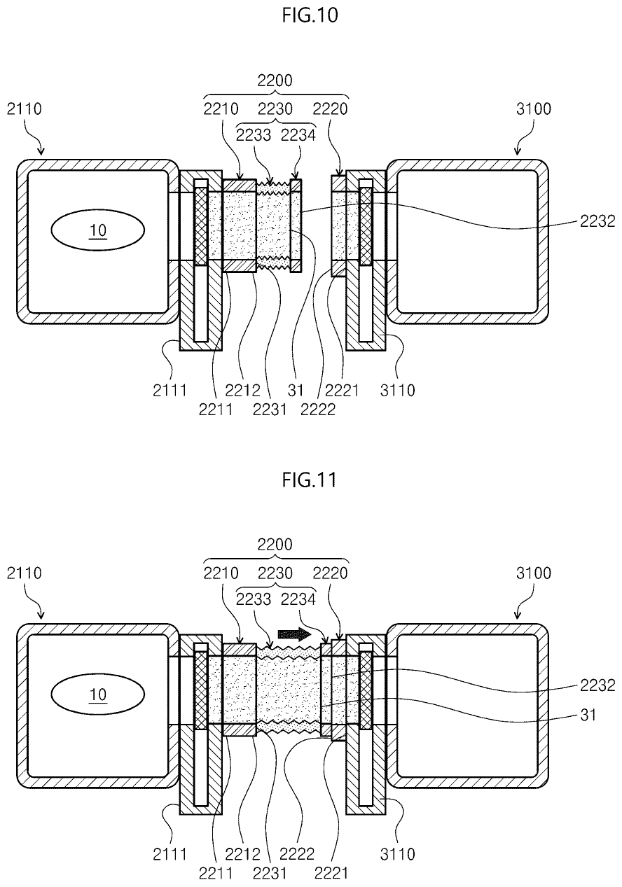

FIGS. 10 to 17 are views illustrating sequentially the process in which a substrate 10 is transferred from the first chamber 2110 to the second chamber 3100 by the chamber docking apparatus 2200 of FIG. 2.

Referring to FIG. 10, according to an example embodiment of the present inventive concept, when the substrate 10 is processed, the inside of the first chamber 2110 and the second chamber 3100 may be in a vacuum state. For example, a depressurization may be performed to lower the internal pressure to a vacuum pressure in the first chamber 2110 so that the substrate 10 may be transferred to the second chamber 3100 in a vacuum state. While the substrate 10 is processed in the first chamber 2110, the length of the bellows portion 2233 may be reduced, and the support portion 2234 and the second chamber 3100 may be separated from each other so that the vibration of the second chamber 3100 is not transmitted to the first chamber 2110. At this time, the pressure of the inside of the chamber docking apparatus 2200 becomes atmospheric pressure.

Referring to FIG. 11, the length of the bellows portion 2233 may be increased so that the substrate 10 may be transferred from the first chamber 2110 to the second chamber 3100, and thus, the support portion 2234 and the second fixed body 2220 are fastened to each other. At this time, the support portion 2234 and the second fixed body 2220 may be fixed to each other by the clamp 2260 of FIG. 5 described above.

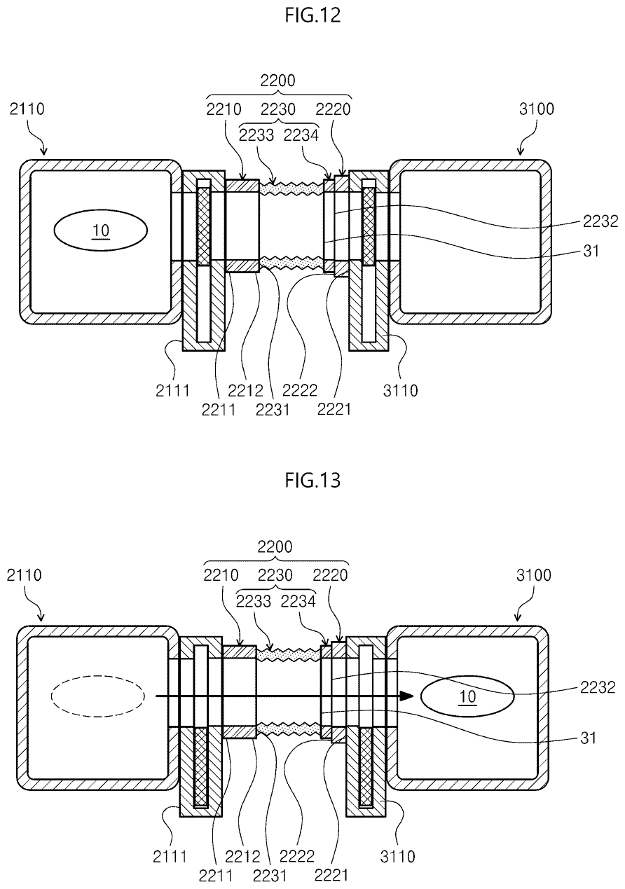

Referring to FIG. 12, when the support portion 2234 and the second fixed body 2220 are connected to each other, the interior of the chamber docking apparatus 2200 is decompressed to a vacuum pressure. In the processes from FIG. 10 to FIG. 12, the first door 2111 and the second door 3110 may be kept closed.

Referring to FIG. 13, when the interior of the chamber docking apparatus 2200 reaches a vacuum pressure, the first door 2111 and the second door 3110 are opened, and the substrate 10 is moved from the first chamber 2110 to the second chamber 3100 by the transfer robot 2120 of FIG. 1.

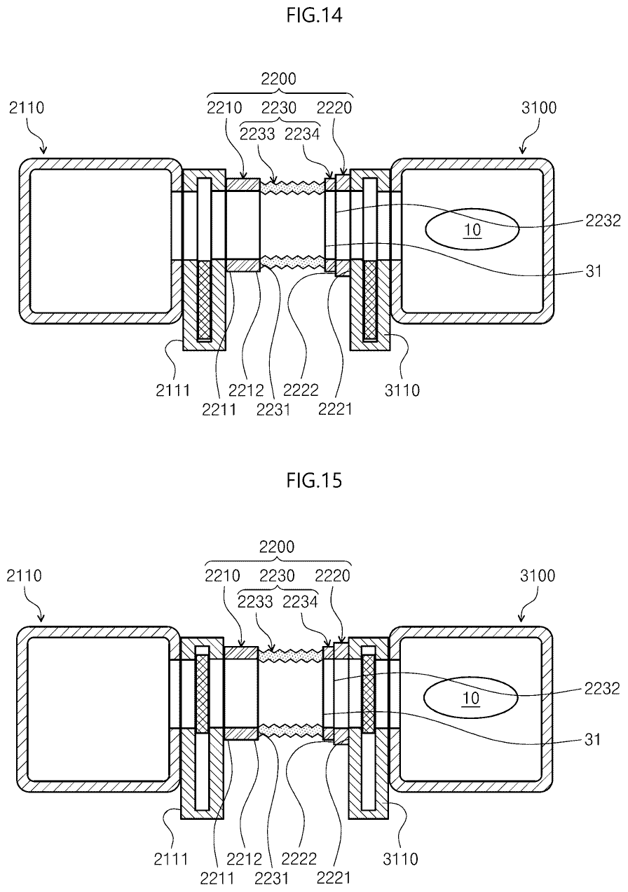

Referring to FIG. 14, the substrate 10 is placed in the second chamber 3100, and the transfer robot 2120 is moved out of the chamber docking apparatus 2200 toward the first chamber 2110.

Referring to FIG. 15, while the substrate 10 is accommodated in the second chamber 3100, the first door 2111 and the second door 3110 are closed.

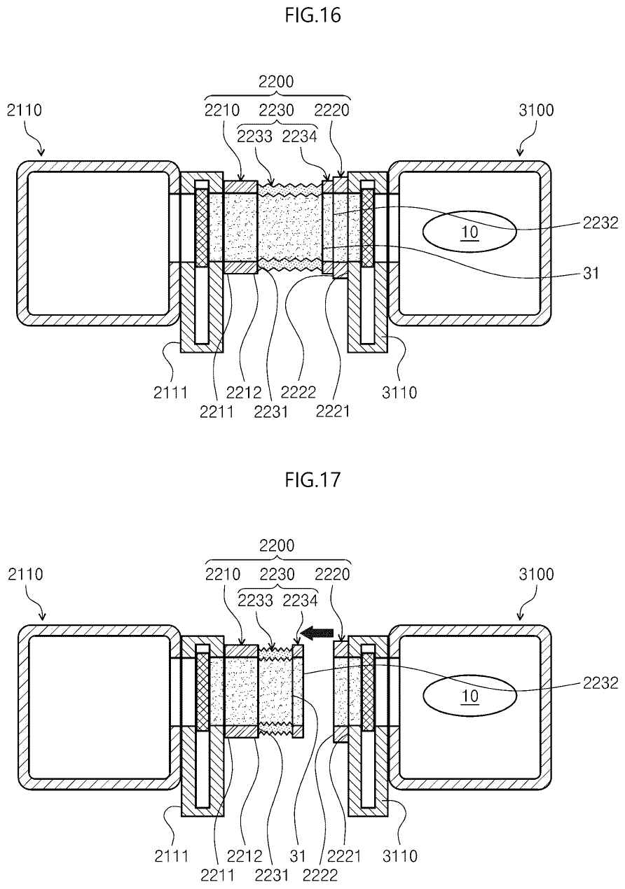

Referring to FIG. 16, the interior of the chamber docking apparatus 2200 is pressurized to atmospheric pressure to separate the length-adjusted body 2230 and the second fixed body 2220 from each other.

Referring to FIG. 17, when the pressure of the chamber docking apparatus 2200 is atmospheric pressure, the length of the length-adjusted body 2230 is shortened to separate the support portion 2234 and the second fixed body 2220 from each other. In this way, when the support portion 2234 and the second fixed body 2220 are separated from each other, the substrate processing process may be performed in the second chamber 3100. Therefore, the vibration of the first chamber 2110 is not transmitted to the second chamber 3100 during the substrate processing process in the second chamber 3100.

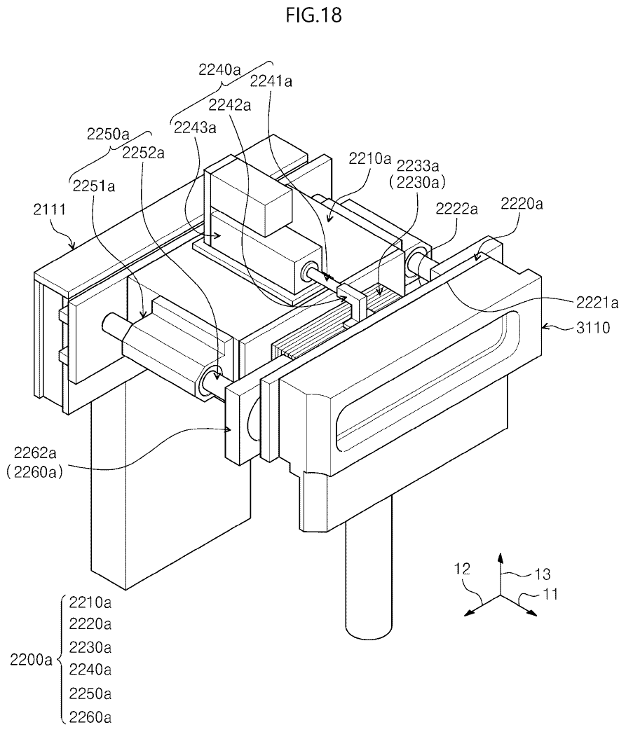

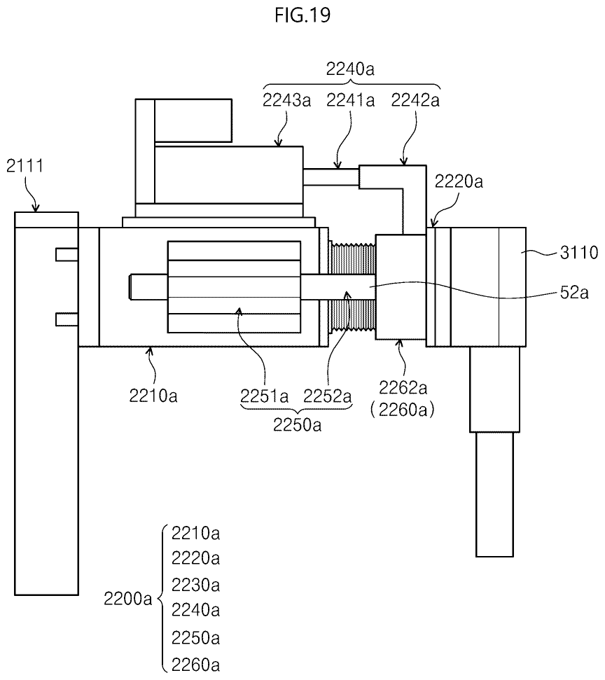

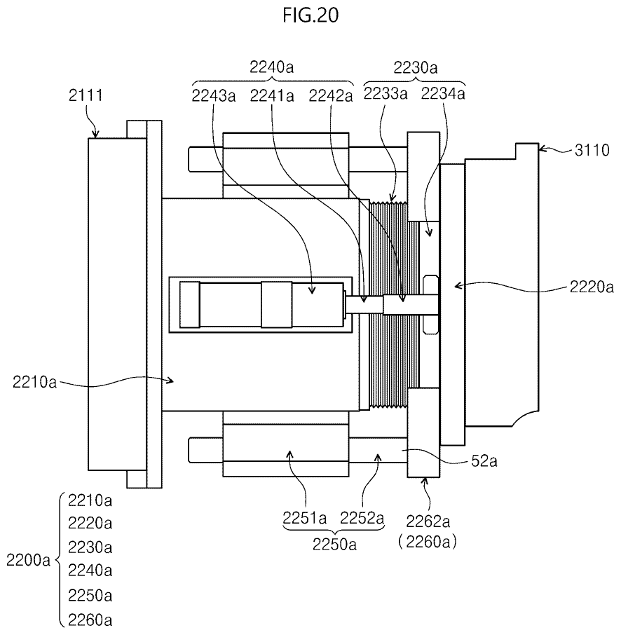

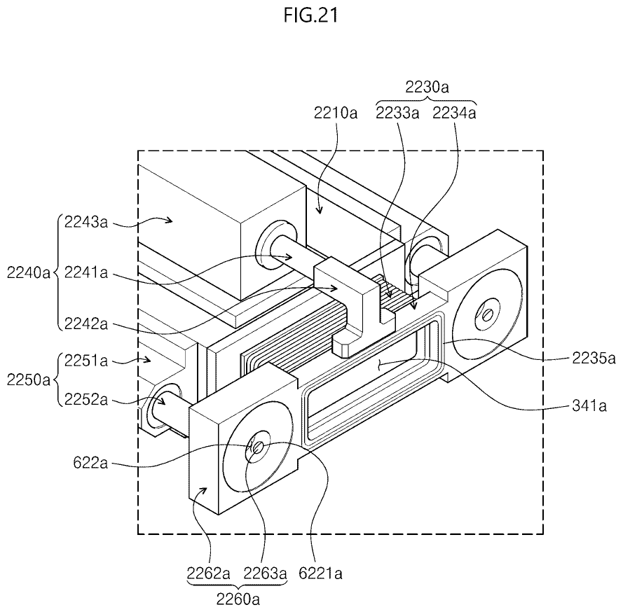

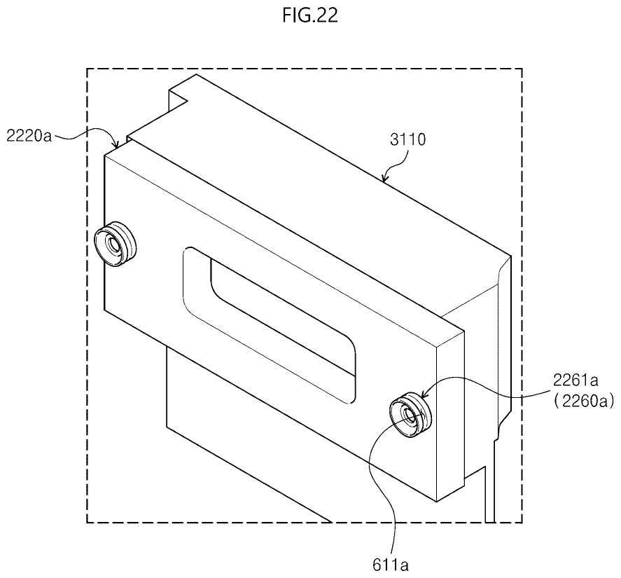

FIG. 18 is a perspective view illustrating a chamber docking apparatus 2200a according to an example embodiment of the present inventive concept. FIG. 19 is a view of the chamber docking apparatus 2200a of FIG. 18 as viewed in the y direction. FIG. 20 is a drawing of the chamber docking apparatus 2200a of FIG. 18 as viewed from above. FIG. 21 is a perspective view illustrating the first fixed body 2210a and the length-adjusted body 2230a of FIG. 18 so that the surface facing the second fixed body 2220a of the support portion 2234a is visible. FIG. 22 is a perspective view illustrating the second fixed body 2220a of FIG. 18 so that the surface thereof facing the length-adjusted body 2230a is visible.

Referring to FIGS. 18 to 22, the clamp 2260a may be provided with a different configuration and structure from the clamp 2260 of FIG. 2. According to an example embodiment of the present inventive concept, the clamp 2260a may include a clamp protrusion 2261a, a clamp body 2262a, a holding piston 2263a and a holding piston drive portion 2264a. In example embodiments of the present inventive concept, the insertion body 2253 of an example embodiment of FIG. 2 is not provided.

The clamp protrusion 2261a protrudes outward from an area, of the second fixed body 2220a, facing the guide shaft 2252a. A piston engaging groove 611a may be formed to be recessed on the outer circumference surface of the clamp protrusion 2261a.

The clamp body 2262a may be fastened to one end 52a of the guide shaft 2252a facing the second fixed body 2220a. The clamp body 2262a may be formed with a protrusion insertion hole 622a into which a clamp protrusion 2261a is inserted. A piston insertion groove 6221a is formed on the inner circumference surface of the protrusion insertion hole 622a so as to be recessed inward.

The holding piston 2263a may be inserted into the piston insertion groove 6221a to be movable along the longitudinal direction of the piston insertion groove 6221a. According to an example embodiment of the present inventive concept, the holding piston 2263a may be provided to be movable between a first position and a second position. The first position may be a position where a part of the holding piston 2263a protrudes from the inner circumference surface of the protrusion insertion hole 622a. The second position may be a position where the holding piston 2263a is located further inside the piston insertion groove 6221a than the first position. The holding piston 2263a may be provided to be inserted into the piston engaging groove 611a and to be engaged when positioned at the first position, and the holding piston 2263a may be discharged from the piston engaging groove 611a and is not engaged when positioned at the second position.

The holding piston drive portion 2264a moves the holding piston 2263a between the first position and the second position.

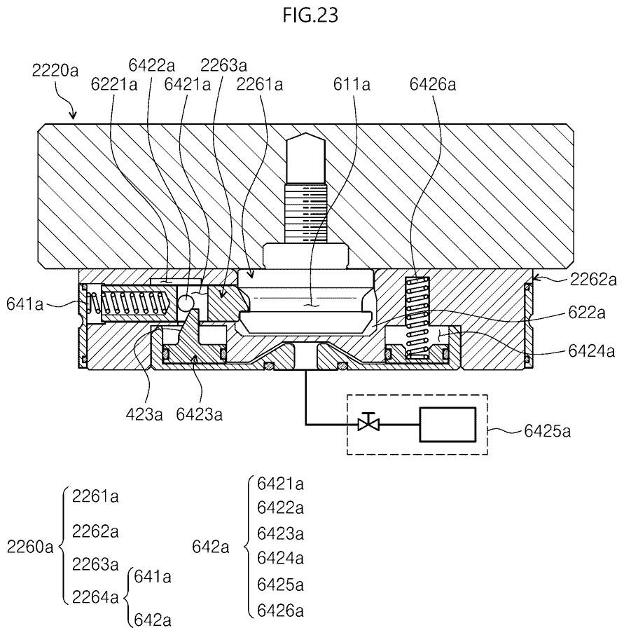

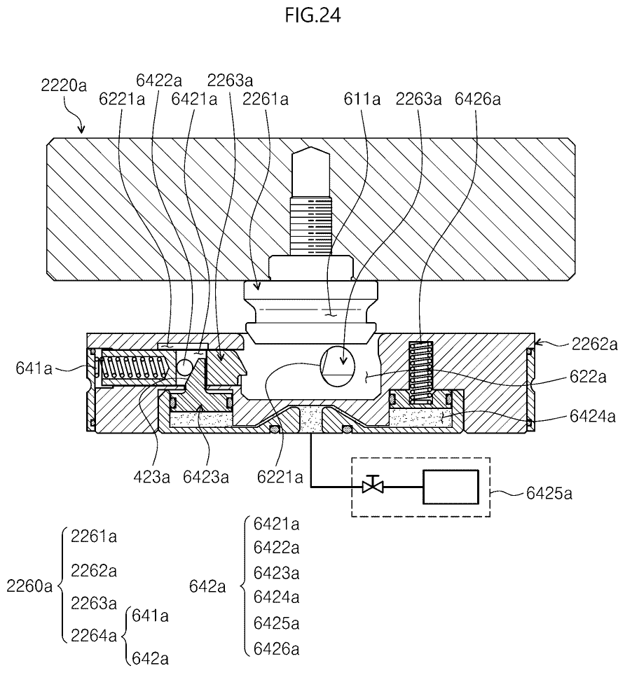

FIG. 23 is a cross-sectional view illustrating the inside of the clamp body 2262a with the clamp protrusion 2261a inserted into the protrusion insertion hole 622a. FIG. 24 is a cross-sectional view illustrating the inside of the clamp body 2262a with the clamp protrusion 2261a separated from the protrusion insertion hole 622a.

Referring to FIGS. 23 and 24, according to an example embodiment of the present inventive concept, the holding piston drive portion 2264a may include an elastic body 641a and a discharge drive portion 642a.

The elastic body 641a may be provided within the clamp body 2262a. The elastic body 641a may apply an elastic force to the holding piston 2263a in a direction in which the holding piston 2263a protrudes from the inner circumference surface of the protrusion insertion hole 622a. Accordingly, when no force is applied by the discharge drive portion 642a, the holding piston 2263a may be positioned at the first position and maintain a state in which the holding piston 2263a protrudes from the inner circumference surface of the protrusion insertion hole 622a, as illustrated in FIG. 23. Therefore, at this time, when the clamp protrusion 2261a is inserted into the protrusion insertion hole 622a, the holding piston 2263a may be pushed into the piston insertion groove 6221a by the clamp protrusion 2261a and moved to the second position, and then moved to the first position by the elastic force of the elastic body 641a and inserted into and caught in the piston engaging groove 611a, so that the support portion 2234 and the second fixed body 2220 may be fixed to each other.

The discharge drive portion 642a may apply force to the holding piston 2263a in a direction toward the second position. According to an example embodiment of the present inventive concept, the discharge drive portion 642a may include a discharge guide hole 6421a, a discharge guide shaft 6422a, a discharge piston 6423a, a cylinder 6424a, an air pressure control portion 6425a and a discharge piston elastic body 6426a.

The discharge guide hole 6421a may be formed by penetrating the holding piston 2263a along the x-direction 11.

The discharge guide shaft 6422a is fastened to the holding piston 2263a so as to cross the discharge guide hole 6421a. The discharge guide shaft 6422a may be provided in a cylindrical shape whose length direction is perpendicular to the x-direction 11 and the moving direction of the holding piston 2263a.

The discharge piston 6423a may be provided at a position farther from the clamp body 2262a along the x-direction 11 than the holding piston 2263a. The discharge piston 6423a may have an inclined surface 423a that is inclined toward the protrusion insertion hole 622a as approaching the clamp body 2262a. The inclined surface 423a may come into contact with the outer circumference surface of the discharge guide shaft 6422a while the discharge piston 6423a moves in a direction that penetrates the discharge guide hole 6421a.

The discharge piston 6423a may move along the cylinder 6424a. The air pressure control portion 6425a controls the air pressure within the cylinder 6424a. When the air pressure inside the cylinder 6424a increases, the discharge piston 6423a moves along the cylinder 6424a in a direction penetrating the discharge guide hole 6421a, and pushes the discharge guide shaft 6422a with its inclined surface 423a, thereby moving the holding piston 2263a to the second position. For example, the discharge piston 6423a is moved in a direction toward the second fixed body 2220a, thereby pushing the discharge guide shaft 6422a with its inclined surface 423a. Accordingly, the holding piston 2263a may be discharged from the piston engaging groove 611a, and the support portion 2234 and the second fixed body 2220a may be separated from each other.

When the air pressure inside the cylinder 6424a decreases, the discharge piston 6423a may be moved in a direction of discharge from the discharge guide hole 6421a by the elastic force of the discharge piston elastic body 6426a. For example, the discharge piston 6423a may move in a direction away from the fixed body 2220a. Accordingly, since the discharge guide shaft 6422a and the inclined surface of the discharge piston 6423a are separated from each other or in less contact with each other, the holding piston 2263a moves to the first position again. For example, the discharge guide shaft 6422a may be in contact with an upper portion of the discharge piston 6423a.

As described above, the clamp 2260 of FIG. 18 may be provided to be connected to the guide shaft 2252a, so that the clamp 2260a of FIG. 18 may perform the function of the insertion body 2253 of FIG. 2 as well as the function of the clamp 2260 of FIG. 2.

According to an example embodiment of the present inventive concept, the length-adjusting driving portion 2240a may be optionally provided on the upper surface of the first fixed body 2210a and the second fixed body 2220a. In addition, since the shaft connection portion 2242a does not structurally interfere with the clamp 2260a, an open area such as the open area 42 of FIG. 6 might not be provided.

Other features of the chamber docking apparatus 2200a of FIG. 18, such as its configuration, structure, function and substrate transfer method, may be provided identically or similarly to the chamber docking apparatus 2200 of FIG. 2. In addition, the chamber docking apparatus 2200a of FIG. 18 may be applied to the substrate processing system 100 and the substrate transfer apparatus 2000 of FIG. 1 by replacing the chamber docking apparatus 2200 of FIG. 2.

As described above, the chamber docking apparatus 2200, 2200a, the substrate transfer apparatus 2000, and the substrate processing system 100 according to example embodiments of the present inventive concept may connect and separate chambers to which the substrate 10 is transferred, thereby preventing vibrations of other devices from being transmitted when performing a substrate processing process.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A chamber docking apparatus connecting a first chamber and a second chamber to each other, comprising:
a first fixed body having a passage penetrating from a first end to the second end thereof through which a substrate passes, and communicating with an entrance of the first chamber;
a second fixed body having a passage penetrating from a first end and to a second end thereof through which the substrate passes, and communicating with an entrance of the second chamber;
a length-adjusted body having a passage through which the substrate passes inside, and configured to adjust in length; and
a length-adjusting driver for adjusting the length of the length-adjusted body, and
wherein a first end of the length-adjusted body is connected to the second end of the first fixed body, and a second end of the length-adjusted body is detachably connected to the second end of the second fixed body, and
wherein the length-adjusted body includes:
a bellows portion including a side wall that includes a bellows structure.

2. The chamber docking apparatus of claim 1,
wherein the length-adjusting driver includes:
a length-adjusting shaft having a first end connected to the second end of the length-adjusted body, and extending parallel to longitudinal direction of the length-adjusted body toward the first fixed body; and
an actuator connected to the first fixed body and moving the length-adjusting shaft along the longitudinal direction of the length-adjusting shaft.

3. The chamber docking apparatus of claim 2,
wherein the actuator is installed on one side surface of the first fixed body, and
wherein the length-adjusting driver further includes:
a shaft connection portion extending outwardly from a side surface of the second end of the length-adjusted body and having an end connected to the first end of the length-adjusting shaft.

4. The chamber docking apparatus of claim 3, further comprising:
a guide portion for guiding a length adjustment direction of the length-adjusted body, and
wherein the guide portion includes:
a guide body installed on one side surface of the first fixed body and having a guide hole formed therethrough along the length adjustment direction; and
a guide shaft engaged with and inserted into the guide hole to be movable along the length adjustment direction and having a first end connected to the second end of the length-adjusted body.

5. The chamber docking apparatus of claim 4,
wherein the first end of the guide shaft protrudes in a direction parallel to the length adjustment direction toward the second fixed body more than the second end of the length-adjusted body, and
wherein the guide portion further includes:
an insertion body installed on the second fixed body and having an insertion hole formed to be engaged with and inserted by the first end of the guide shaft.

6. The chamber docking apparatus of claim 4 further comprising:
a clamp fixing the second fixed body and the length-adjusted body to each other while the second fixed body and the length-adjusted body are in contact with each other.

7. The chamber docking apparatus of claim 6,
wherein the length-adjusted body further includes:
a support portion extending from a first end of the bellows portion toward the second fixed body, and having outer circumference surface protruding outwardly more than an outer circumference of the bellows portion, wherein the support portion has an area corresponding to an open area of the first end of the bellows portion, and
wherein the clamp includes:
a piston spaced outwardly from an outer circumference of the second fixed body, and provided to be reciprocally movable along a length adjustment direction relative to the second fixed body;
a piston driver that reciprocally moves the piston along the length adjustment direction;
a holding frame having a first end connected to an end of the piston that faces the first fixed body to be rotatable about an axis that extends in a y direction; and
a guide frame having a first end and a second end, wherein the first end of the guide frame is connected between the first end and the second end of the holding frame to be rotatable about an axis that extends in the y direction, and wherein the second end of the guide frame is connected to a position between the piston and the second fixed body and farther from the first fixed body than the end of the piston to be rotatable about an axis that extends in the y direction, and
wherein the second end of the holding frame comes into contact with a surface of the support portion, which faces the first fixed body and protrudes outward from the bellows portion, when the piston is positioned at a first position, and is spaced from the support portion when the piston is positioned at a position farther from the first fixed body than when the piston is positioned at the first position.

8. The chamber docking apparatus of claim 7,
wherein the shaft connection portion has an area overlapping the clamp when viewed along the length adjustment direction, and
wherein the clamp passes the area.

9. The chamber docking apparatus of claim 6,
wherein the clamp includes:
a clamp protrusion protruding from an area of the second fixed body facing the guide shaft;
a clamp body fastened to a first end of the guide shaft toward the second fixed body and having a protrusion insertion hole into which the clamp protrusion is inserted;
a holding piston inserted into a piston insertion groove formed on an inner circumference surface of the protrusion insertion hole, and movable between a first position and a second position, wherein the holding piston protrudes from the inner circumference surface when at the first position, and wherein the holding piston is located further inside the piston insertion groove in comparison to being at the first position when at the second position; and
a holding piston drive portion moving the holding piston between the first position and the second position, and
wherein a piston engaging groove is formed on an outer circumference surface of the clamp protrusion, wherein the holding piston is inserted into and engaged with the piston engaging groove when the holding piston is positioned at the first position and wherein the holding piston is discharged from and not engaged with the piston engaging groove when the holding piston is positioned at the second position.

10. A substrate transfer apparatus comprising:
a chamber docking apparatus connecting substrate processing devices to each other; and
a substrate transfer portion transferring the substrate between the substrate processing devices through the chamber docking apparatus, and
wherein the substrate transfer portion includes:
a first chamber having a space therein where the substrate is transferred and communicating with one of the substrate processing devices; and
a transfer robot provided in the first chamber and transferring the substrate between the substrate processing devices through the first chamber and the chamber docking apparatus, and
wherein the other of the substrate processing devices includes:
a second chamber having a space therein where the substrate is processed, and
wherein the chamber docking apparatus includes:
a first fixed body having a passage penetrating from a first end to a second end thereof through which the substrate passes, and communicating with an entrance of one of the first chamber or the second chamber;
a second fixed body having a passage penetrating from a first end to a second end thereof through which the substrate passes, and communicating with an entrance of the other of the first chamber or the second chamber;
a length-adjusted body having a passage through which the substrate passes inside, and configured to adjust in length; and
a length-adjusting driver for adjusting the length of the length-adjusted body, and
wherein a first end of the length-adjusted body is connected to the second end of the first fixed body, and the second end of the length-adjusted body is detachably connected to the second end of the second fixed body, and
wherein the length-adjusted body includes:
a bellows portion including a side wall that includes a bellows structure.

11. The substrate transfer apparatus of claim 10,
wherein the length-adjusting driver includes:
a length-adjusting shaft having a first end connected to the second end of the length-adjusted body, and extending parallel to longitudinal direction of the length-adjusted body toward the first fixed body; and
an actuator connected to the first fixed body and moving the length-adjusting shaft along the longitudinal direction of the length-adjusting shaft.

12. The substrate transfer apparatus of claim 11,
wherein the actuator is installed on one side surface of the first fixed body, and
wherein the length-adjusting driver further includes:
a shaft connection portion extending outwardly from a side surface of the second end of the length-adjusted body and having an end connected to the first end of the length-adjusting shaft.

13. The substrate transfer apparatus of claim 10,
wherein the chamber docking apparatus further includes:
a guide portion for guiding a length adjustment direction of the length-adjusted body, and
wherein the guide portion includes:
a guide body installed on one side surface of the first fixed body and having a guide hole formed therethrough along the length adjustment direction; and
a guide shaft engaged with and inserted into the guide hole to be movable along the length adjustment direction and having a first end connected to the second end of the length-adjusted body.

14. The substrate transfer apparatus of claim 13,
wherein the first end of the guide shaft protrudes in a direction parallel to the length adjustment direction toward the second fixed body more than the second end of the length-adjusted body, and
wherein the guide portion further includes:
an insertion body installed on the second fixed body and having an insertion hole formed to be engaged with and inserted by the first end of the guide shaft.

15. The substrate transfer apparatus of claim 10,
wherein the chamber docking apparatus further includes:
a clamp fixing the second fixed body and the length-adjusted body to each other while the second fixed body and the length-adjusted body are in contact with each other.

16. A substrate processing system comprising:
a first substrate processing device processing a substrate;
a second substrate processing device processing the substrate before or after the first substrate processing device; and
a substrate transfer apparatus transferring the substrate between the first substrate processing device and the second substrate processing device, and
wherein the substrate transfer apparatus includes:
a chamber docking apparatus connecting the first substrate processing device and the second substrate processing device to each other; and
a substrate transfer portion transferring the substrate between the first substrate processing device and the second substrate processing device through the chamber docking apparatus,
wherein the substrate transfer portion includes:
a first chamber having a space therein where the substrate is transferred and communicating with the first substrate processing device, and
a transfer robot provided in the first chamber and transferring the substrate between the first substrate processing device and the second substrate processing device through the first chamber and the chamber docking apparatus, and
wherein the second substrate processing device includes:
a second chamber having a space therein where the substrate is processed, and
wherein the chamber docking apparatus includes:
a first fixed body having a passage penetrating from a first end to a second end thereof through which the substrate passes, and communicating with an entrance of one of the first chamber and the second chamber;
a second fixed body having a passage penetrating from a first end to a second end thereof through which the substrate passes, and communicating with an entrance of the other of the first chamber or the second chamber;
a length-adjusted body having a passage through which the substrate passes inside, and configured to adjust in length; and
a length-adjusting driver for adjusting the length of the length-adjusted body, and
wherein a first end of the length-adjusted body is connected to the second end of the first fixed body, and the second end of the length-adjusted body is detachably connected to the second end of the second fixed body, and
wherein the length-adjusted body includes:
a bellows portion including a side wall that includes a bellows structure.

17. The substrate processing system of claim 16,
wherein the length-adjusting driver includes:
a length-adjusting shaft having a first end connected to the second end of the length-adjusted body, and extending parallel to longitudinal direction of the length-adjusted body toward the first fixed body; and
an actuator connected to the first fixed body and moving the length-adjusting shaft along the longitudinal direction of the length-adjusting shaft.

18. The substrate processing system of claim 17,
wherein the actuator is installed on one side surface of the first fixed body, and
wherein the length-adjusting driver further includes:
a shaft connection portion extending outwardly from a side surface of the second end of the length-adjusted body and having an end connected to the first end of the length-adjusting shaft.

19. The substrate processing system of claim 16,
wherein the chamber docking apparatus further includes:
a guide portion for guiding a length adjustment direction of the length-adjusted body, and
wherein the guide portion includes:
a guide body installed on one side surface of the first fixed body and having a guide hole formed therethrough along the length adjustment direction; and
a guide shaft engaged with and inserted into the guide hole to be movable along the length adjustment direction and having a first end connected to the second end of the length-adjusted body.

20. The substrate processing system of claim 19,
wherein the first end of the guide shaft protrudes in a direction parallel to the length adjustment direction toward the second fixed body more than the second end of the length-adjusted body, and
wherein the guide portion further includes:
an insertion body installed on the second fixed body and having an insertion hole formed to be engaged with and inserted by the first end of the guide shaft.
